(19) United States
(12) Patent Application Publication
(10) Pub. No.: US 2021/0335827 A1
(43) Pub. Date: Oct. 28, 2021

(54) ARRAY SUBSTRATE AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Pian Xiao, Shenzhen (CN)

(21) Appl. No.: 16/624,411

(22) PCT Filed: Nov. 11, 2019
(86) PCT No.: PCT/CN2019/117044

§ 371 Date: Dec. 19, 2019

(30) Foreign Application Priority Data
Sep. 17, 2019 (CN) 201910877717.7

(51) Int. Cl. H01L 27/12

(52) U.S. Cl. CPC H01L 27/124; H01L 27/1237

(57) ABSTRACT

An array substrate and a display panel are provided. The array substrate includes scanning lines, data lines, pixel electrodes disposed between the scanning lines and the data lines, and thin film transistors electrically connected to the scanning lines, data lines, and pixel electrodes. By disposing openings on positions of gate electrodes of the thin film transistors corresponding to drain electrodes, a problem of inconsistent parasitic capacitance between the gate electrodes and the drain electrodes of the thin film transistors due to position shifting of the drain electrodes of the thin film transistors can be solved, thereby improving display quality of the display panel using the array substrate.

### FIELD OF INVENTION

The present disclosure relates to the field of display technology, and particularly relates to an array substrate and a display panel.

### BACKGROUND OF INVENTION

In display technology, displaying and swapping of images of display devices are usually realized by cooperation of scanning lines and data lines disposed on an array substrate. Furthermore, the scanning lines and the data lines on the array substrate are arranged in a crisscross pattern to form a plurality of subpixel units, and each subpixel unit has one scanning line and one data line which are corresponding thereto. Therefore, display devices with many subpixel units require a large number of scanning lines and data lines disposed. In order to reduce the number of data lines of display devices, data line sharing technology is developed, which is a technology that adjacent subpixels share one data line and adjacent subpixels use different scanning lines. This can achieve the purpose of reducing the number of data lines by half; therefore, it is widely used in the field of display technology.

Because manufacturing processes of array substrates based on the data line sharing technology are difficult to achieve perfect manufacturing accuracy, a shifting situation of all source electrodes and drain electrodes of thin film transistors related to the data lines often occurs. FIG. 1 shows the situation of all source electrodes and drain electrodes of thin film transistors related to the data lines shifting right. In this situation, an overlapping area of a drain electrode 14a3 and a gate electrode 14a2 of a first thin film transistor 14a located on a right side of a data line 12 is reduced, and an overlapping area of a drain electrode 14b3 and a gate electrode 14b2 of a second thin film transistor 14b located on a left side of the data line 12 is increased, which causes a parasitic capacitance between the drain electrode 14a3 and the gate electrode 14a2 of the first thin film transistor 14a to be reduced, and causes a parasitic capacitance between the drain electrode 14b3 and the gate electrode 14b2 of the second thin film transistor 14b to be increased, making data signals received by pixel electrodes 13 on the right side and the left side have difference in intensity, thereby causing pixel units 15 on the right side and the left side to have different brightness, which leads to an occurrence of dark fringe phenomenon on a display panel.

In manufacturing processes of array substrates based on the data line sharing technology, a shifting situation of all source electrodes and drain electrodes of thin film transistors related to the data lines often occurs, thereby affecting uniformity of display brightness of display panels.

### SUMMARY OF INVENTION

In order to solve the technical problem mentioned above, the present disclosure provides solution as follows:

The present disclosure provides an array substrate, including:

A plurality of scanning lines, which are disposed along a first direction and used to provide a plurality of scanning signals to the array substrate.

A plurality of data lines, which are disposed along a second direction and are used to provide a plurality of data signals to the array substrate.

A plurality of pixel electrodes, which are disposed in gaps encircled by the scanning lines and the data lines.

A plurality of thin film transistors, wherein a gate electrode of each of the thin film transistors is electrically connected to the scanning line, a source electrode of each of the thin film transistors is electrically connected to the data line, and a drain electrode of each of the thin film transistors electrically is connected to the pixel electrode.

Furthermore, a plurality of openings are disposed on the gate electrodes of the thin film transistors corresponding to positions of the drain electrodes of the thin film transistors.

In the array substrate of the present disclosure, the openings penetrate the gate electrodes of the thin film transistors along a thickness direction of the gate electrodes of the thin film transistors.

In the array substrate of the present disclosure, an end of the drain electrode of each of the thin film transistors close to the source electrode of each of the thin film transistors is defined as a first end, and an end of the drain electrode of each of the thin film transistors electrically connected to one of the pixel electrodes is a second end.

The openings are located inside the gate electrodes of the thin film transistors.

A plurality of vertical projections of the first ends on the gate electrodes of the thin film transistors fall into the openings.

In the array substrate of the present disclosure, the gate electrodes of the thin film transistors are rectangular frame structures.

In the array substrate of the present disclosure, a side of the gate electrode of each of the thin film transistors close to the drain electrode of each of the thin film transistors is defined as a first side, a side of the gate electrode of each of the thin film transistors close to the source electrode of each of the thin film transistors is a second side, an end of the drain electrode of each of the thin film transistors close to the source electrode of each of the thin film transistors is a first end, and an end of the drain electrode of each of the thin film transistors connected to the pixel electrodes is a second end.

The openings penetrate the first sides.

A plurality of vertical projections of the first ends on the gate electrodes of the thin film transistors fall into the openings.

In the array substrate of the present disclosure, the gate electrodes of the thin film transistors are concave structures.

In the array substrate of the present disclosure, the openings penetrate the second sides.

In the array substrate of the present disclosure, the gate electrode of each of the thin film transistors has two sections oppositely disposed.

In the array substrate of the present disclosure, the openings are square openings.

In the array substrate of the present disclosure, a left side and a right side of each of the data lines are electrically connected to the thin film transistors, and each of the thin film transistors is electrically connected to one of the pixel electrodes.

In the array substrate of the present disclosure, the thin film transistors connected to the same data lines are disposed in a stagger manner on the first direction.

In the array substrate of the present disclosure, the source electrodes and the drain electrodes of the thin film transistors and the data lines are located on a same layer of the array substrate.

In the array substrate of the present disclosure, the gate electrodes of the thin film transistors and the scanning lines are located on a same layer of the array substrate.

In the array substrate of the present disclosure, the array substrate further includes an insulation layer, the insulation layer is disposed between the gate electrodes, and the source and drain electrodes, and the insulation layer is used to isolate electrical connections between the gate electrodes and the source and drain electrodes.

In the array substrate of the present disclosure, the pixel electrodes are made of indium tin oxide.

The present disclosure further provides a display panel, including an array substrate, and the array substrate includes:

A plurality of scanning lines, which are disposed along a first direction and are used to provide a plurality of scanning signals to the array substrate.

A plurality of data lines, which are disposed along a second direction and are used to provide a plurality of data signals to the array substrate.

A plurality of pixel electrodes, which are disposed in gaps encircled by the scanning lines and the data lines.

A plurality of thin film transistors, and a gate electrode of each of the thin film transistors is electrically connected to the scanning line, a source electrode of each of the thin film transistors is electrically connected to the data line, and a drain electrode of each of the thin film transistors is electrically connected to the pixel electrode.

Furthermore, openings are disposed on the gate electrodes of the thin film transistors corresponding to positions of the drain electrodes of the thin film transistors.

In the display panel of the present disclosure, an end of the drain electrode of each of the thin film transistors close to the source electrode of each of the thin film transistors is defined as a first end, and a plurality of vertical projections of the first ends on the gate electrodes of the thin film transistors fall into the openings.

In the display panel of the present disclosure, the openings penetrate the gate electrodes of the thin film transistors along a thickness direction of the gate electrodes of the thin film transistors to make the gate electrodes of the thin film transistors form rectangular frame structures.

In the display panel of the present disclosure, the openings penetrate the gate electrodes of the thin film transistors along a thickness direction of the gate electrodes of the thin film transistors to make the gate electrodes of the thin film transistors form concave structures.

In the display panel of the present disclosure, the openings penetrate the gate electrodes of the thin film transistors along a thickness direction of the gate electrodes of the thin film transistors to make the gate electrode of each of the thin film transistors have two separated sections.

By disposing the openings on the gate electrodes of the thin film transistors, the array substrate and the display panel provided by the present disclosure can solve the problem of the inconsistent parasitic capacitance between the gate electrodes and the drain electrodes of the thin film transistors due to the shift of the position of the drain electrodes of the thin film transistors, and can improve consistency of the data signals transmitted to the pixel electrodes through the thin film transistors, thereby improving display quality of the display panel using the array substrate.

### DESCRIPTION OF DRAWINGS

To more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further without making any inventive efforts.

FIG. 1 is a structural schematic diagram of a data line sharing type of an array substrate in the prior art, wherein data lines and all source electrodes and drain electrodes of thin film transistors shift right due to manufacturing accuracy.

FIG. 2 is a structural schematic diagram of an array substrate provided by an embodiment of the present disclosure.

FIG. 3 is a structural schematic diagram of the thin film transistor 24 illustrated in FIG. 2.

FIG. 4 is a cross section along A-A′ line of the thin film transistor 24 illustrated in FIG. 3.

FIG. 5 is another structural schematic diagram of the thin film transistor 24 illustrated in FIG. 2.

FIG. 6 is another structural schematic diagram of the thin film transistor 24 illustrated in FIG. 2.

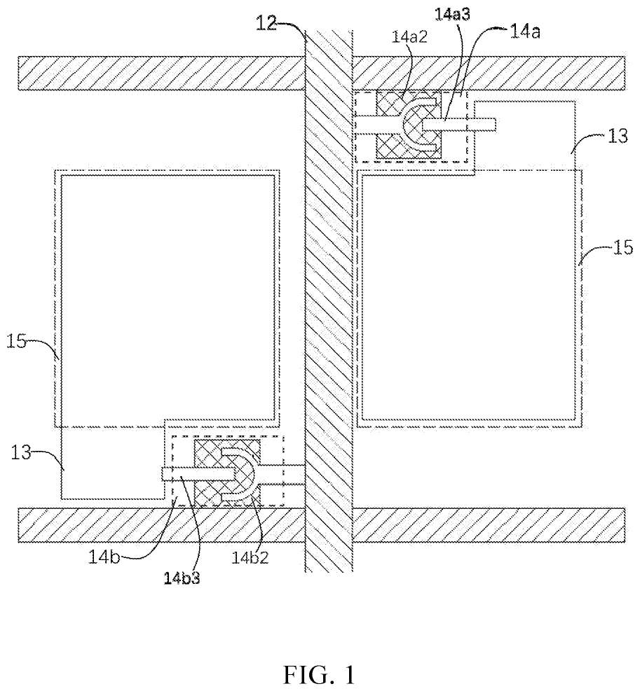

### DETAILED DESCRIPTION OF PREFERRED EMBODIMENTS

The descriptions of embodiments below refer to accompanying drawings in order to illustrate certain embodiments which the present disclosure can implement. The directional terms of which the present disclosure mentions, for example, “top”, “bottom”, “upper”, “lower”, “front”, “rear”, “left”, “right”, “inside”, “outside”, “side”, etc., only refer to directions of the accompanying figures. Therefore, the used directional terms are for illustrating and understanding the present disclosure, but not for limiting the present disclosure. In the figures, units with similar structures are indicated by the same reference numerals.

An embodiment of the present disclosure provides an array substrate, which includes a plurality of thin film transistors. By disposing a plurality of openings on positions of gate electrodes of the thin film transistors corresponding to drain electrodes of the thin film transistors, the problem of inconsistent data signals received by pixel electrodes due to position shifting of the drain electrodes of the thin film transistors can be solved, thereby improving display uniformity of the display panel using the array substrate.

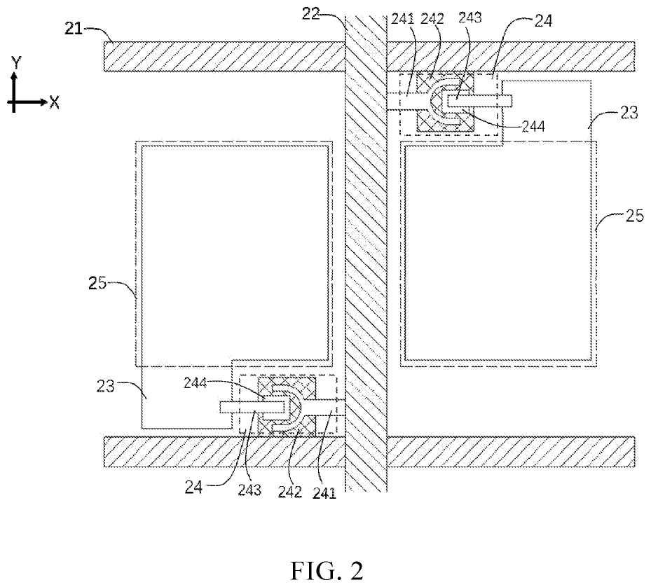

Illustrated in FIG. 2 is a structural schematic diagram of an array substrate pair provided by an embodiment of the present disclosure. The array substrate includes scanning lines 21, data lines 22, pixel electrodes 23, and thin film transistors 24.

The scanning lines 21 are disposed along a first direction X. The data lines 22 are disposed along a second direction Y. Optionally, the first direction X is perpendicular to the second direction Y. The scanning lines 21 are used for providing scanning signals to the array substrate. The data lines 22 are used for providing data signals to the array substrate. It should be understood, that the array substrate includes a plurality of the scanning lines 21 and a plurality of the data lines 22, and the scanning lines 21 and the data lines 22 encircle to form a plurality of pixel units 25. The pixel units 25 are the basic display units on the array substrate.

The pixel electrodes 23 are disposed in gaps encircled by the scanning lines 21 and the data lines 22. Specifically, the pixel electrodes 23 are disposed in the pixel units 25, and the pixel electrodes 23 are used for providing electrode signals to the pixel units 25. Optionally, the pixel electrodes 23 are made of indium tin oxide (ITO), which is a transparent conductive material.

A gate electrode 242 of each of the thin film transistors 24 is electrically connected to the scanning line 21, a source electrode 241 of each of the thin film transistors 24 is electrically connected to the data line 22, and a drain electrode 243 of each of the thin film transistors 24 is electrically connected to the pixel electrode 23. Under control of the scanning signals provided by the scanning lines 21, the thin film transistors 24 are used for transmitting the data signals provided by the data lines 22 to the pixel electrodes 23 to control display functions of the pixel units 25.

Specifically, two adjacent pixel units 25 on the first direction X share one data line 22, and each of the left side and the right side of the data line 22 is electrically connected to one of the thin film transistors 24, and each of the thin film transistors 24 is electrically connected to one of the pixel electrodes 23. Therefore, data line sharing of the array substrate is realized, and a number of the data lines on the array substrate is reduced.

Specifically, the source electrodes 241 and the drain electrodes 243 of the thin film transistors 24 are located on a same layer of the array substrate with the data lines 22, so that the source electrodes 241 and the drain electrodes 243 of the thin film transistors 24 and the data lines 22 can be manufactured by a same manufacturing process. The gate electrodes of the thin film transistors 24 are located on a same layer of the array substrate with the scanning lines 21 to allow the gate electrodes of the thin film transistors 24 and the scanning lines 21 to be manufactured by a same manufacturing process. The array substrate includes the thin film transistors 24 which are connected to the two sides of the data lines 22.

Specifically, a plurality of openings 244 are disposed on the gate electrodes 242 of the thin film transistors 24 corresponding to positions of the drain electrodes 243 of the thin film transistors 24. It should be noted that the positions on the gate electrodes 242 of the thin film transistors 24 corresponding to the drain electrodes 243 are vertical projections of the drain electrodes 243 on the gate electrodes 242.

It should be understood that in a manufacturing process of the data lines 22 and the source electrodes 241 and the drain electrodes 243 of the thin film transistors, because perfect manufacturing accuracy is difficult to achieve, this causes an occurrence of a phenomenon of the data lines 22 and all the source electrodes 241 and the drain electrodes 243 of the thin film transistors shifting right or shifting left, which causes overlapping areas of the drain electrodes 243 and the gate electrodes 242 of the thin film transistors on the two sides of the data lines 22 to have differences. By disposing the openings 244 on the gate electrodes 242 of the thin film transistors, the embodiments of the present disclosure can eliminate difference of parasitic capacitance due to the overlapping areas of the drain electrodes 243 and the gate electrodes 242 of the thin film transistors on the two sides of the data lines 22 being different, thereby ensuring that the pixel electrodes 23 on the two sides of the data lines 22 receive same data signals, and promoting display uniformity of the display panel made of the array substrate.

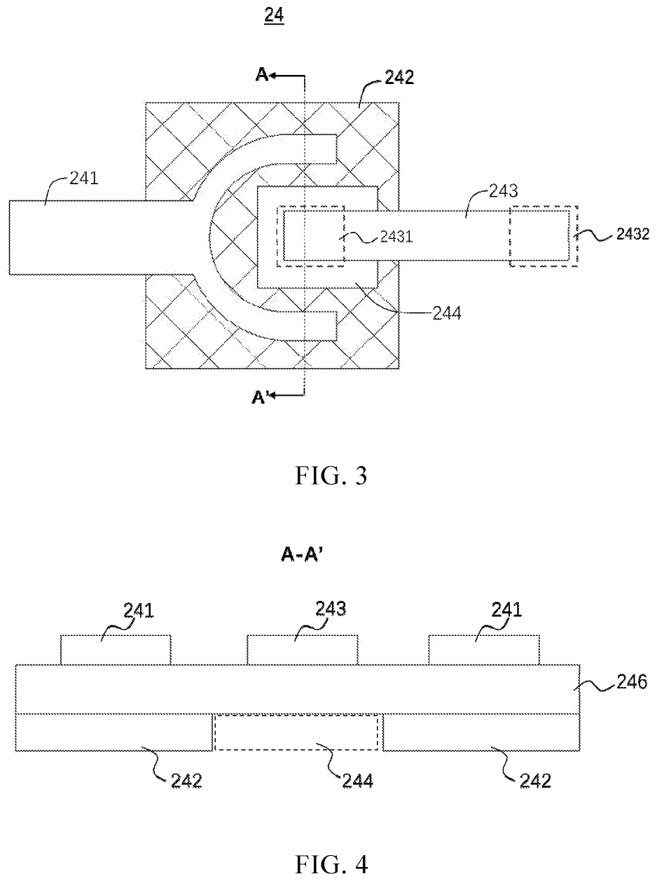

Specifically, as illustrated in FIG. 3 and FIG. 4, FIG. 3 is a structural schematic diagram of the thin film transistor 24 illustrated in FIG. 2, and FIG. 4 is a cross section along A-A′ line of the thin film transistor illustrated in FIG. 3. The thin film transistors 24 further include insulation layers 246 located between the gate electrodes 242 and the source electrodes 241, and the insulation layers 246 are made of an insulation material, such as silicon nitride, etc. Optionally, the openings 244 are square openings.

Specifically, the openings 244 penetrate the gate electrodes 242 of the thin film transistors along a thickness direction of the gate electrodes 242 of the thin film transistors to ensure the gate electrodes 242 of the thin film transistors can be completely hollowed out on positions of the openings 244.

An end of the drain electrode 241 of each thin film transistor close to the source electrode 241 of each thin film transistor is defined as a first end 2431, and an end of the drain electrode 243 of each thin film transistor electrically connected to one of the pixel electrodes 23 (referring to FIG. 2) is a second end. Optionally, the openings 244 are located inside the gate electrodes 242 of the thin film transistors, that is, the openings 244 are encircled by the gate electrodes 242 of the thin film transistors, and the openings 244 do not form penetration effect on the gate electrodes 242 of the thin film transistors on a width direction or on a length direction, thereby reducing impact of the openings 244 on functions of the gate electrodes 242 of the thin film transistors.

A plurality of vertical projections of the first ends 2431 on the gate electrodes 242 of the thin film transistors fall into the openings 244 to ensure that the parasitic capacitance between the gate electrodes 242 and the drain electrodes 243 will not change when shifting of positions of the drain electrodes 243 occurs. It should be noted that a top view approach is used in FIG. 3 to illustrate structural characteristics of the thin film transistor 24. Therefore, the vertical projection of the drain electrodes 243 of the thin film transistors on the gate electrodes 242 can be directly seen in the positional relationship illustrated in FIG. 3. In addition, a perspective approach is used in FIG. 3 to illustrate structural characteristics of the thin film transistor 24, and the insulation layer 246 (referring to FIG. 4) between the gate electrode 242 of the thin film transistor and the source electrode 241 and the gate electrode 243 of the thin film transistor is omitted. It should be understood, that the gate electrode 242 of the thin film transistor and the source electrode 241 and the gate electrode 243 of the thin film transistor maintain electrical insulation.

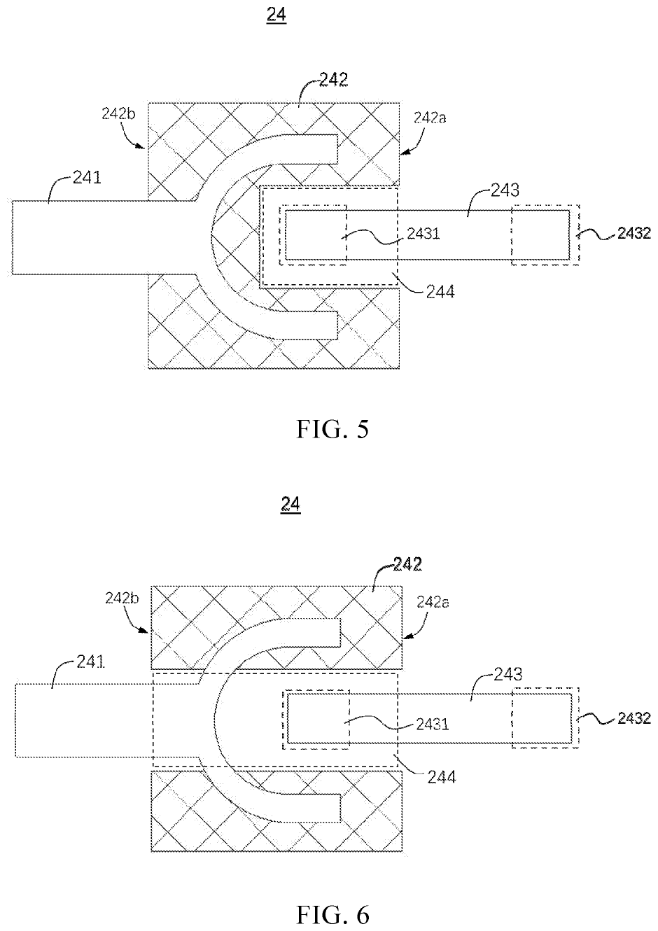

Optionally, illustrated in FIG. 5 is another structural schematic diagram of the thin film transistor 24 illustrated in FIG. 2. A side of the gate electrode 242 of each thin film transistor close to the drain electrode 243 of each thin film transistor is defined as a first side 242a, and a side of the gate electrode 242 of each thin film transistor close to the source electrode 241 of each thin film transistor is a second side 242b.

The openings 244 penetrate the first sides 242a to make the gate electrode 242 of the thin film transistor form a concave structure. The vertical projections of the first ends 2431 of the drain electrodes 243 of the thin film transistors on the gate electrodes 242 of the thin film transistors fall into the openings 244 to ensure that the parasitic capacitance between the gate electrodes 242 and the drain electrodes 243 will not change when shifting of positions of the drain electrodes 243 of the thin film transistors occur, thereby ensuring the data signals transmitted to the pixel electrodes 23 by the thin film transistors 24 (referring to FIG. 2) are same and stable. It should be noted that a top view approach is used in FIG. 5 to illustrate structural characteristics of the thin film transistor 24. Therefore, the vertical projection of the drain electrode 243 of the thin film transistor on the gate electrode 242 can be directly seen in the positional relationship illustrated in FIG. 5. In addition, a perspective approach is used in FIG. 5 to illustrate structural characteristics of the thin film transistor 24, and the insulation layer 246 (referring to FIG. 4) between the gate electrode 242 of the thin film transistor and the source electrode 241 and the gate electrode 243 of the thin film transistor is omitted. It should be understood, that the gate electrode 242 of the thin film transistor and the source electrode 241 and the gate electrode 243 of the thin film transistor maintain electrical insulation.

Optionally, illustrated in FIG. 6 is another structural schematic diagram of the thin film transistor 24 illustrated in FIG. 2. The opening 244 penetrates the gate electrode 242 of the thin film transistor along a direction parallel to the drain electrode of the thin film transistor; that is, the opening 244 penetrates the first side 242a of the thin film transistor and the second side 242b of the thin film transistor. The vertical projections of the first ends 2431 of the drain electrodes 243 of the thin film transistors on the gate electrodes 242 of the thin film transistors fall into the openings 244 to ensure that the parasitic capacitance between the gate electrodes 242 and the drain electrodes 243 will not change when shifting of positions of the drain electrodes 243 occurs, thereby ensuring the data signals transmitted to the pixel electrode 23 by the thin film transistor 24 (referring to FIG. 2) are same and stable. In addition, disposing the openings 244 to penetrate the gate electrodes 242 of the thin film transistors can ensure that the parasitic capacitance between the gate electrodes 242 and the drain electrodes 243 will still not change even when a greater shifting of positions of the drain electrodes 243 occurs. It should be noted that a top view approach is used in FIG. 6 to illustrate structural characteristics of the thin film transistor 24. Therefore, the vertical projection of the drain electrode 243 of the thin film transistor on the gate electrode 242 can be directly seen in the positional relationship illustrated in FIG. 6. In addition, a perspective approach is also used in FIG. 6 to illustrate structural characteristics of the thin film transistor 24, and the insulation layer 246 (referring to FIG. 4) between the gate electrode 242 of the thin film transistor and the source electrode 241 and the gate electrode 243 of the thin film transistor is omitted. It should be understood, that the gate electrode 242 of the thin film transistor and the source electrode 241 and the gate electrode 243 of the thin film transistor maintain electrical insulation.

In summary, by disposing the openings on the gate electrodes of the thin film transistors, the array substrate provided by the embodiments of the present disclosure can solve the problem of inconsistent parasitic capacitance between the gate electrodes and the drain electrodes of the thin film transistors due to the shifting of the position of the drain electrodes of the thin film transistors, and can improve consistency of the data signals transmitted to the pixel electrodes through the thin film transistors.

An embodiment of the present disclosure further provides a display panel, and the display panel includes any one of the array substrates of the embodiments mentioned above. By disposing openings on the gate electrodes of the thin film transistors, consistency of the data signals transmitted to the pixel electrodes through the thin film transistors is ensured, thereby allowing the display panel to have better display uniformity and improving display quality of the display panel.

It should be noted that although the present disclosure has disclosed the specific embodiments as above, the above-mentioned embodiments are not to limit to the present disclosure. A person skilled in the art can make any change and modification; therefore, the scope of protection of the present disclosure is subject to the scope defined by the claims.

What is claimed is:

1. An array substrate, comprising:
a plurality of scanning lines disposed along a first direction and used to provide a plurality of scanning signals to the array substrate;
a plurality of data lines disposed along a second direction and used to provide a plurality of data signals to the array substrate;
a plurality of pixel electrodes disposed in gaps encircled by the scanning lines and the data lines; and
a plurality of thin film transistors, wherein a gate electrode of each of the thin film transistors is electrically connected to the scanning lines, a source electrode of each of the thin film transistors is electrically connected to the data lines, and a drain electrode of each of the thin film transistors is electrically connected to the pixel electrodes; and
wherein a plurality of openings are disposed on the gate electrodes of the thin film transistors corresponding to positions of the drain electrodes of the thin film transistors.

2. The array substrate as claimed in claim 1, wherein the openings penetrate the gate electrodes of the thin film transistors along a thickness direction of the gate electrodes of the thin film transistors.

3. The array substrate as claimed in claim 1, wherein an end of the drain electrode of each of the thin film transistors close to the source electrode of each of the thin film transistors is defined as a first end, and an end of the drain electrode of each of the thin film transistors electrically connected to one of the pixel electrodes is a second end;
the openings are located inside the gate electrodes of the thin film transistors; and
a plurality of vertical projections of the first ends on the gate electrodes of the thin film transistors fall into the openings.

4. The array substrate as claimed in claim 3, wherein the gate electrodes of the thin film transistors are rectangular frame structures.

5. The array substrate as claimed in claim 1, wherein a side of the gate electrode of each of the thin film transistors close to the drain electrode of each of the thin film transistors is defined as a first side, a side of the gate electrode of each of the thin film transistors close to the source electrode of each of the thin film transistors is a second side, an end of the drain electrode of each of the thin film transistors close to the source electrode of each of the thin film transistors is a first end, and an end of the drain electrode of each of the thin film transistors connected to the pixel electrodes is a second end;
the openings penetrate the first sides; and
a plurality of vertical projections of the first ends on the gate electrodes of the thin film transistors fall into the openings.

6. The array substrate as claimed in claim 5, wherein the gate electrodes of the thin film transistors are concave structures.

7. The array substrate as claimed in claim 5, wherein the openings penetrate the second sides.

8. The array substrate as claimed in claim 7, wherein the gate electrode of each of the thin film transistors has two sections oppositely disposed.

9. The array substrate as claimed in claim 1, wherein the openings are square openings.

10. The array substrate as claimed in claim 1, wherein a left side and a right side of each of the data lines are electrically connected to the thin film transistors, and each of the thin film transistors is electrically connected to one of the pixel electrodes.

11. The array substrate as claimed in claim 10, wherein the thin film transistors connected to the same data lines are disposed in a stagger manner on the first direction.

12. The array substrate as claimed in claim 1, wherein the source electrodes and the drain electrodes of the thin film transistors and the data lines are located on a same layer of the array substrate.

13. The array substrate as claimed in claim 1, wherein the gate electrodes of the thin film transistors and the scanning lines are located on a same layer of the array substrate.

14. The array substrate as claimed in claim 1, wherein the array substrate comprises an insulation layer, the insulation layer is disposed between the gate electrodes, and the source and drain electrodes, and the insulation layer is used to isolate electrical connections between the gate electrodes and the source and drain electrodes.

15. The array substrate as claimed in claim 1, wherein the pixel electrodes are made of indium tin oxide.

16. A display panel, comprising an array substrate, and the array substrate comprising:
a plurality of scanning lines disposed along a first direction and used to provide a plurality of scanning signals to the array substrate;
a plurality of data lines disposed along a second direction and used to provide a plurality of data signals to the array substrate;
a plurality of pixel electrodes disposed in gaps encircled by the scanning lines and the data lines; and
a plurality of thin film transistors, wherein a gate electrode of each of the thin film transistors is electrically connected to the scanning lines, a source electrode of each of the thin film transistors is electrically connected to the data lines, and a drain electrode of each of the thin film transistors is electrically connected to the pixel electrodes; and
wherein a plurality of openings are disposed on the gate electrodes of the thin film transistors corresponding to positions of the drain electrodes of the thin film transistors.

17. The display panel as claimed in claim 16, wherein an end of the drain electrode of each of the thin film transistors close to the source electrode of each of the thin film transistors is defined as a first end, and a plurality of vertical projections of the first ends on the gate electrodes of the thin film transistors fall into the openings.

18. The display panel as claimed in claim 17, wherein the openings penetrate the gate electrodes of the thin film transistors along a thickness direction of the gate electrodes of the thin film transistors to make the gate electrodes of the thin film transistors form rectangular frame structures.

19. The display panel as claimed in claim 17, wherein the openings penetrate the gate electrodes of the thin film transistors along a thickness direction of the gate electrodes of the thin film transistors to make the gate electrodes of the thin film transistors form concave structures.

20. The display panel as claimed in claim 17, wherein the openings penetrate the gate electrodes of the thin film transistors along a thickness direction of the gate electrodes of the thin film transistors to make the gate electrode of each of the thin film transistors have two separated sections.
